(19) United States
(12) Patent Application Publication
(10) Pub. No.: US 2019/0227109 A1
(43) Pub. Date: Jul. 25, 2019

(54) QUANTIFYING RANDOM TIMING JITTER THAT INCLUDES GAUSSIAN AND BOUNDED COMPONENTS

(71) Applicant: Tektronix, Inc., Beaverton, OR (US)

(72) Inventor: Mark L. Guenther, Portland, OR (US)

(21) Appl. No.: 16/255,717

(22) Filed: Jan. 23, 2019

Related U.S. Application Data
(60) Provisional application No. 62/620,957, filed on Jan. 23, 2018.

(51) Int. Cl. G01R 29/26

(52) U.S. Cl. CPC G01R 29/26

(57) ABSTRACT

A test and measurement device for determining types of jitter, the test and measurement instrument including an input for receiving an input signal, a converter coupled to the input and structured to generate a spectral power signal for non-deterministic jitter from the received input signal, a threshold detector structured to identify ranges of the spectral power signal that are in excess of a threshold, a filter structured to filter the identified ranges of the spectral power signal, a Gaussian detector structured to determine whether the filtered ranges of the spectral power signal contain primarily Gaussian or non-Gaussian jitter, and a Q-scale analyzer structured to perform further signal analysis only if the Gaussian detector determined that the jitter in the filtered ranges of the spectral power signal contains a mixture of Gaussian and non-Gaussian jitter.

### PRIORITY

This disclosure claims benefit of U.S. Provisional Application No. 62/620,957, titled “QUANTIFYING RANDOM TIMING JITTER THAT INCLUDES GAUSSIAN AND BOUNDED COMPONENTS,” filed on Jan. 23, 2018, which is incorporated herein by reference in its entirety.

### FIELD OF THE INVENTION

This disclosure is directed to systems and methods related to test and measurement systems, and in particular, to a test and measurement instrument that can more accurately quantify random timing jitter that is a mixture of Gaussian and bounded components.

### BACKGROUND

Many modern electronic devices and communication systems transfer digital information from a transmitter to a receiver across a channel using a serialized stream of digital bits. It can be of great interest of users to measure the quality of the transmitted or received signal to predict error rate. In particular, jitter analysis refers to the process of measuring the displacement in time of each rising or falling waveform edge from its ideal position, which is jitter, and then analyzing the jitter to identify distinct subcomponents, either for the purposes of predicting bit error rate or developing or debugging an electronic circuit.

Several well-known jitter analysis methods performed by various test and measurement instruments have relied on spectral analysis to separate multiple forms of deterministic jitter from random jitter. However, using these techniques have proved to be problematic when the random jitter contains both Gaussian (unbounded) and non-Gaussian bounded components. This can be challenging because both of these components can occupy the same spectral range with comparable spectral density, and both can be either “flat” or slow varying with frequency. Since Gaussian jitter has a dramatically different impact on bit error rate than bounded jitter has, and the consequences of misidentifying these jitter components is serious.

Embodiments of the disclosure address these and other deficiencies of the prior art.

### BRIEF DESCRIPTION OF THE DRAWINGS

Aspects, features and advantages of embodiments of the present disclosure will become apparent from the following description of embodiments in reference to the appended drawings in which:

FIG. 1 is an example spectral power plot of jitter on a serial data waveform, shown with a linear frequency scale.

FIG. 2 is the example spectral power plot of FIG. 1, shown with a logarithmic horizontal scale and an adaptive threshold useful for identifying and separating deterministic jitter.

FIG. 3 is an example spectral power plot with a linear horizontal scale having an adaptive threshold that does not distinguish between Gaussian and non-Gaussian jitter.

FIG. 4 is an example Q-scale plot for a purely Gaussian distribution.

FIG. 5 is an example Q-scale plot having a bounded component in addition to the Gaussian distribution.

FIG. 6 is an example Q-scale plot with a reduced amplitude of the bounded component.

FIG. 7 is an example Q-scale plot in which the standard deviation of the Gaussian jitter has been reduced so as to be commensurate with the bounded component amplitude.

FIG. 8 is the example Q-scale plot of FIG. 7, re-scaled horizontally.

FIG. 9 is an example block diagram of a test and measurement instrument, according to some embodiments.

FIG. 10 is an example operation of the test and measurement instrument of FIG. 9, according to some embodiments.

FIG. 11 is a more-detailed example operation of the test and measurement instrument of FIG. 9, according to some embodiments.

FIG. 12 is an example power spectral density plot with a frequency-adaptive threshold that exhibits a low rate of amplitude change per Hertz of frequency change.

FIG. 13 is an example power spectral plot after application of a filter designed according to some embodiments of the disclosure.

### DESCRIPTION

As mentioned above, conventional jitter analysis methods have relied on spectral analysis to separate multiple forms of deterministic jitter from random jitter. Typically these methods compare a digital Fourier Transform (DFT) of the jitter to a fixed or frequency-adaptive magnitude threshold to identify deterministic peaks.

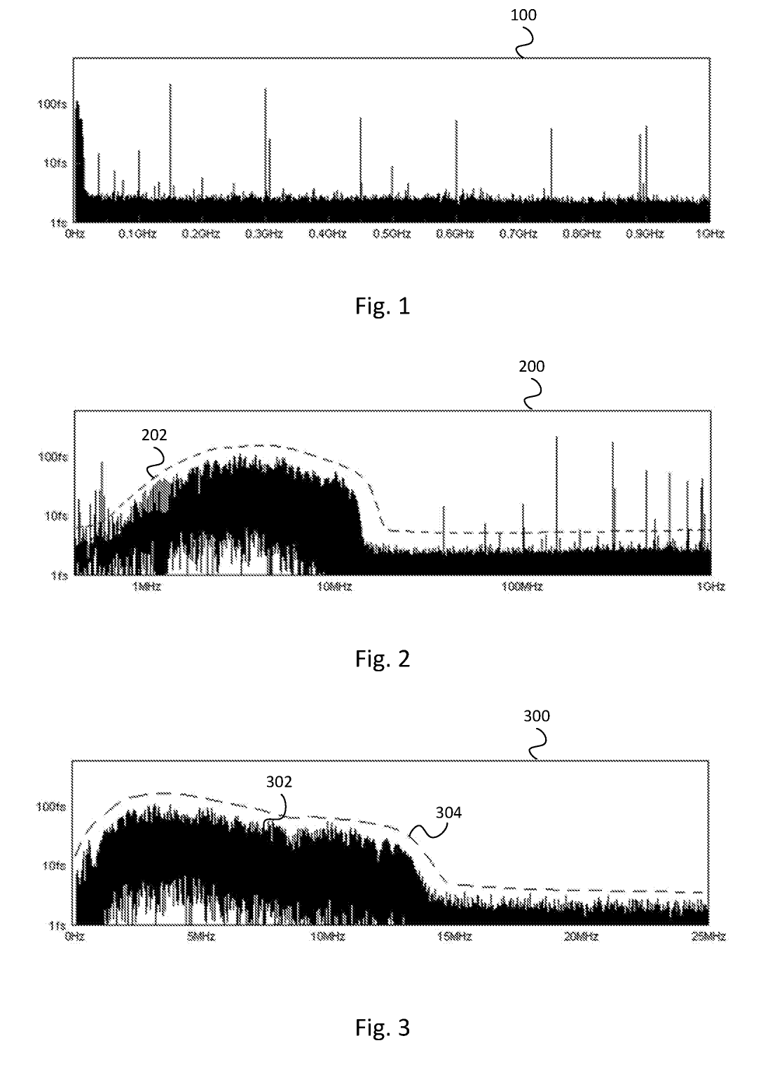

An adaptive magnitude threshold is desirable since, even though Gaussian random noise is most commonly “white” (having equal power per Hertz of bandwidth), it can also follow a 1/f or 1/r profile, where f is frequency, or can be shaped by the poles and zeros of equalizers that compensate for channel loss. An adaptive magnitude threshold may change with frequency dynamically enough to follow variations in the noise floor, but it is desirable to prevent the adaptive threshold from adapting so fast that it follows the very signals it is supposed to detect. FIG. 1 is a representative spectral power plot 100 of a signal with jitter on a linear frequency time scale. FIG. 2 is a representative spectral plot 200 of the same signal with jitter of FIG. 1, but on a log horizontal scale. An adaptive threshold 202 is also shown. Spectral peaks that exceed the adaptive threshold 202 are considered to be deterministic jitter, and they can then be filtered from the overall jitter to leave what might be presumed to be entirely random jitter.

An even more difficult problem with conventional test and measurement instruments has been to analyze a distribution of random jitter that contains both Gaussian and non-Gaussian, also referred to herein as bounded, components. This can be challenging because both of these components can occupy the same spectral range with a comparable spectral density, as mentioned above. Both components may also be either “flat” or slowly varying with frequency. It is common for bounded random jitter to appear as a broad hump or bulge in a power spectrum, usually at a relatively low frequency.

FIG. 3 illustrates a spectral power plot 300 with bounded random jitter, which appears as a broad hump 302 or bulge in a power spectrum. Depending on the slope with which the spectral hump 302 rises from the surrounding white Gaussian noise floor, the bounded jitter 302 can often look much like a rise in Gaussian jitter that follows a 1/f or 1/f² profile. A typical adaptive threshold 304 designed to detect deterministic jitter could adapt to the hump 302 without detecting anything, as shown in FIG. 3.

Potentially even more challenging than the examples described above, non-Gaussian jitter may be present that has a spectral density lower than, or on par with, that of the white Gaussian noise. In these cases, there may be an insignificant spectral bulge, or no bulge at all, to detect via an adaptive threshold.

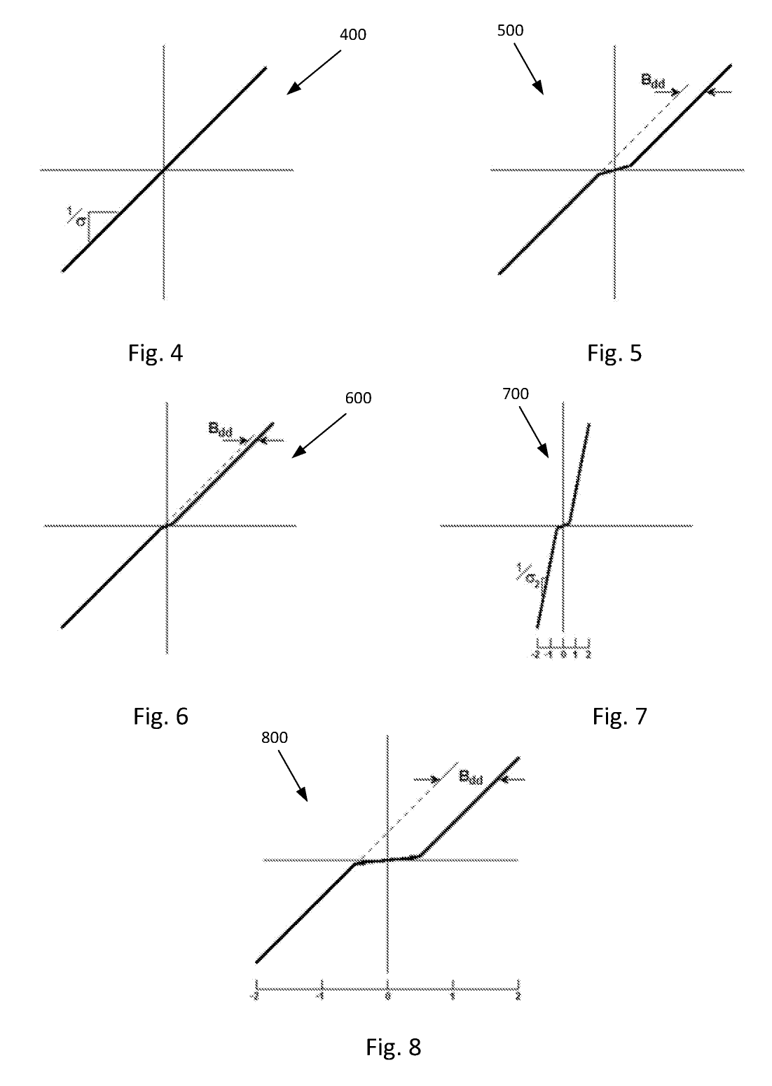

Some well-known methods have been developed that use tail-fit or Q-scale to analyze an entire jitter spectrum, either before or after filtering out recognizably deterministic components. However, these methods can be troublesome because it can be common for a small amount of bounded jitter to be overwhelmed by a much larger amount of Gaussian jitter, thus making the magnitude of the bounded jitter hard to detect and characterize. This is illustrated in FIGS. 4-6.

On a Q-scale plot 400, shown in FIG. 4, a Gaussian distribution with standard deviation, σ, appears as a straight line, with a slope equal to 1/σ. When an independent, bounded distribution of small magnitude is added to the Gaussian distribution, the probability density functions (PDFs) of the two distributions are convolved. On the Q-scale plot 500 in FIG. 5, introduction of the bounded distribution causes the two ends of the straight line to shift outward, maintaining the same asymptotic slope. The value B_{dd} is the dual-Dirac amplitude of the bounded distribution, which is a useful measure of the strength of the bounded distribution. For real statistical data, one of ordinary skill in the art will appreciate that the lines on the Q-scale plots 400 and 500 are not as straight as the plots suggests, and there may be some variability in the slopes of the asymptotes, even if chosen with care.

The Q-scale plot 600 in FIG. 6, illustrates when the amplitude of the bounded distribution is small in relation to the Gaussian a. There is a risk that the amplitude B_{dd} will be on par with the variability in the asymptote fit, leading to large variability in the estimate of B_{dd}. The Q-scale plot 700 in FIG. 7 illustrates when the standard deviation of the Gaussian jitter is somehow reduced from its original value σ to a much smaller value, σ₂. The Q-scale plot 800 in FIG. 8 illustrates the sample plot, but when re-scaled horizontally. It can be seen that when the bounded jitter is on a comparable scale to the Gaussian jitter, the Q-scale approach is much more easily able to determine the bounded jitter's magnitude.

A higher-order statistic mathematical test, known as kurtosis, can help assess whether a statistical sample has a Gaussian distribution. For Gaussian-distributed random variables, kurtosis tends to the value 3.0 as the sample size grows. For bounded distributions, the kurtosis tends to a number less than 3.0. For this reason, the term “excess kurtosis” is sometimes used, which is defined as kurtosis −3.0, so a bounded distribution will tend toward an excess kurtosis less than zero.

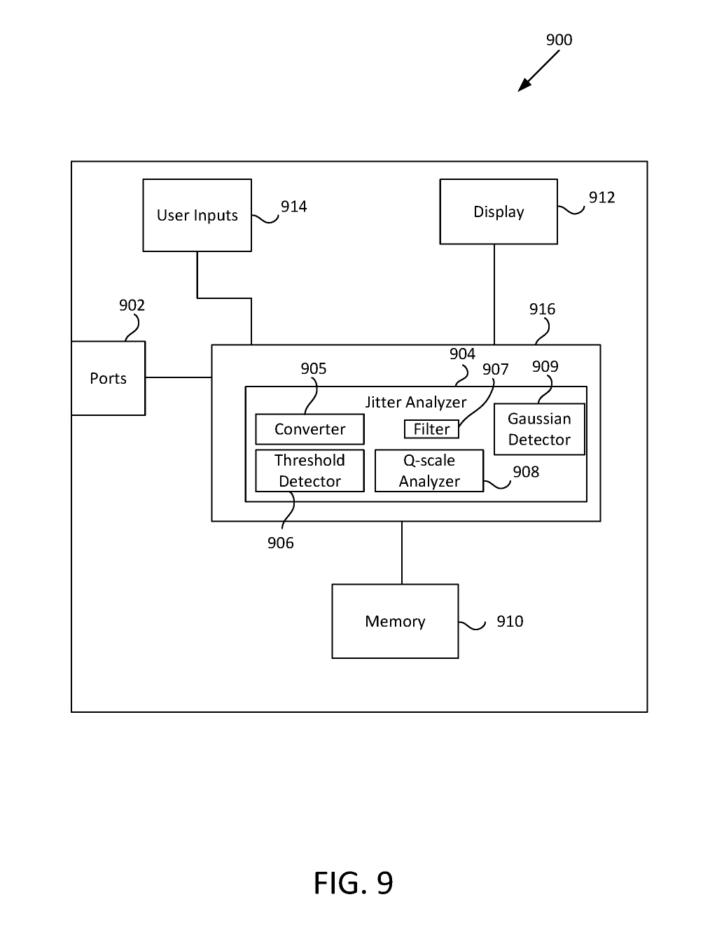

FIG. 9 is a block diagram of an example test and measurement instrument 900, such as an oscilloscope, for implementing embodiments of the disclosure disclosed herein. The instrument 900 includes a plurality of ports 902 which may be any electrical signaling medium and may act as a network interface. Ports 902 may include receivers, transmitters, and/or transceivers. The ports 902 are connected to a network to receive data from a device under test. The ports 902 are coupled with one or more processors 916. The one or more processors 916 may include a jitter analyzer 904, which may receive one or more inputs from the ports 902. Although only one processor 916 is shown in FIG. 9 for ease of illustration, as will be understood by one skilled in the art, multiple processors of varying types may be used in combination, rather than a single processor 916.

The ports 902 can also be connected to a measurement unit in the test instrument 900, not depicted. Such a measurement unit can include any component capable of measuring aspects (e.g., voltage, amperage, amplitude, etc.) of a signal received via ports 902. The pipeline depicted by ports 902 through a processor and/or jitter analyzer 904 can include conditioning circuits, an analog to digital converter, and/or other circuitry.

The jitter analyzer 904 may be implemented as any processing circuity, such as an application specific integrated circuit (ASIC), a digital signal processor (DSP), a field programmable gate array (FPGA), etc. In some embodiments, the jitter analyzer 904 may be configured to execute instructions from memory 910 and may perform any methods and/or associated steps indicated by such instructions. In other embodiments, the jitter analyzer 904 may include components separate from the one or more processors 916, such as various filters or signal converters.

The jitter analyzer 904 may include, for example, a converter 905, a threshold detector 906, a filter 907, a Q-scale analyzer 908, and a Gaussian Detector 909. As will be discussed in further detail below, the converter 905 may receive an input signal through ports 902 and convert the input signal to a spectral power signal. The threshold detector 906 may then identify ranges of the spectral power signal that are in excess of a threshold. The filter 907 is structured to filter the identified ranges of the spectral power signal and may be, for example, a digital bandpass filter or a digital low-pass filter. The Gaussian detector 909 determines whether the filtered ranges include primarily Gaussian jitter or non-Gaussian jitter, using a kurtosis analysis. When the filtered ranges are determined to include non-Gaussian jitter, then a Q-scale analyzer 908 may perform further analysis on the filtered ranges to determine the Gaussian jitter and the non-Gaussian jitter in the filtered ranges. The analysis may then be displayed to a user on a display 912.

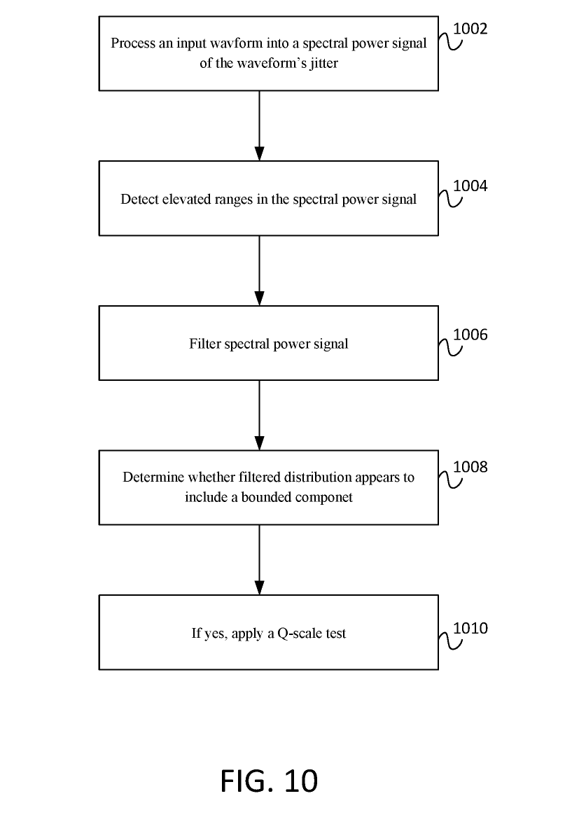

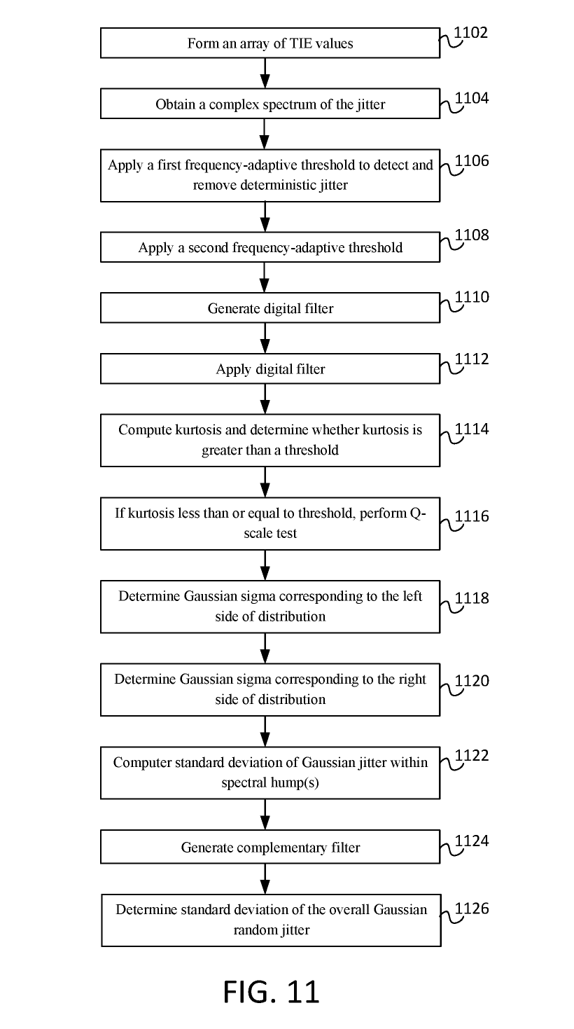

Memory 910 may be implemented as processor cache, random access memory (RAM), read only memory (ROM), solid state memory, hard disk drive(s), or any other memory type. Memory 910 acts as a medium for storing data, computer program products, and other instructions, and providing such data/products/instruction to the data record generator 904 for computation as desired. Memory 910 also stores measured signal responses (e.g. waveforms), timestamps, and instructions for the operations discussed below in FIGS. 10 and 11, and/or other data for use by the jitter analyzer 904.

User inputs 914 are coupled to the jitter analyzer 904. User inputs 914 may include a keyboard, mouse, trackball, touchscreen, and/or any other controls employable by a user to interact with the jitter analyzer 904 via a GUI on a display 912. The display 912 may be a digital screen, a cathode ray tube based display, or any other monitor to display test results, timestamps, packet time lines, or other results to a user as discussed herein. While the components of test instrument 900 are depicted as being integrated with test instrument 900, it will be appreciated by a person of ordinary skill in the art that any of these components can be external to test instrument 900 and can be coupled to test instrument 900 in any conventional manner (e.g., wired and/or wireless communication media and/or mechanisms).

In some embodiments of the disclosure, the test and measurement instrument 900 may include a separate processor (not shown) connected to the jitter analyzer 904. In some embodiments, the jitter analyzer 904 may connect to the memory 910, display 912, and user inputs 914 through the separate processor, as will be understood by one skilled in the art.

FIG. 10 illustrates example operations of the test and measurement instrument 900, and more specifically, the jitter analyzer 904, according to some embodiments of the disclosure. Processor 916 may process an input waveform into a spectral power signal representing the non-deterministic jitter on the waveform in operation 1002. In operation 1004, the jitter analyzer 904 detects elevated ranges in the spectral power signal, using a threshold. Then, in operation 1006, the spectral power signal may be filtered, such as by using a bandpass filter, to isolate the elevated ranges from the spectral power signal. In operation 1008, the jitter analyzer 904 can determine whether the filtered distribution appears to include a bounded component. If yes, in operation 1010, a Q-scale test can be applied. Then, the different types of jitter in the input signal may be displayed to a user

FIG. 11 illustrates the operation discussed with respect to FIG. 10 in additional detail. In operation 1102, the processor 916 and/or the jitter analyzer 904 can form an array of time interval error (TIE) values for a received input signal. This may be done, for example, by detecting actual times when the waveform crosses a chosen detection voltage, such as an auto-detect mid-threshold of the input signal and/or based on an input received from the user. A corresponding array of ideal times representing a “perfect” or jitter-free clock, according to some clock recovery strategy, which may be set by the user, is formed. Then the two formed arrays are subtracted from each other to obtain the array of TIE values.

In operation 1104, the processor 916 and/or the jitter analyzer may obtain a complex spectrum of the jitter by multiplying the TIE array with an appropriate processing window, such as a Blackman window and performing a Fourier transform. An estimate of the power spectral density of the overall jitter is obtained by taking a magnitude of the resulting complex array.

In operation 1106, a frequency-adaptive threshold may be applied to the power spectral density estimate. This frequency-adaptive threshold is determined for every frequency point in the spectrum. That is, this frequency-adaptive threshold varies with each point in the spectrum. Points at which the spectral power exceeds the frequency-adaptive threshold are identified as deterministic jitter, such as discussed above with respect to FIG. 1. The corresponding points of the complex jitter spectrum are set to zero magnitude to remove the deterministic jitter from the spectrum. This yields the complex spectrum of the non-deterministic jitter, and the magnitude of this complex spectrum is the power spectral density estimate of the non-deterministic jitter.

Operations 1102, 1104, and 1106 may be performed using methods, such as, but not limited to, the methods described in U.S. Pat. Nos. 6,832,172 and 6,853,933, each of which is incorporated herein by reference in its entirety.

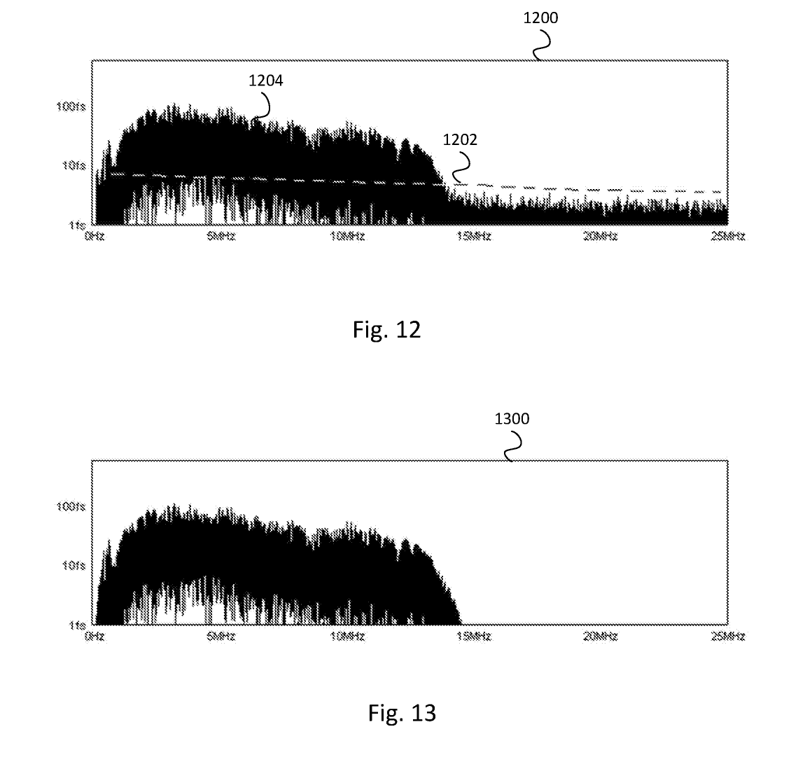

In operation 1108, a second frequency-adaptive threshold can be applied to the power spectral density estimate of the non-deterministic jitter. The second frequency-adaptive threshold 1202 may have a slower adaptation rate than the frequency-adaptive threshold in operation 1106, so that even broad humps 1204 in the spectrum are detected, as shown on the plot 1200 of FIG. 12. The second frequency-adaptive threshold may be determined by averaging the points from the first frequency-adaptive threshold over multiple frequency points, for example, hundreds of frequency points, rather than determining the frequency-adaptive threshold for each frequency point, as discussed above in operation 1106 and exemplified by U.S. Pat. No. 6,853,933.

In operation 1110, the processor 916 and/or the jitter analyzer 904 generates a digital filter, such that the bandpass region of the filter corresponds to the areas of the spectrum that exceed the second frequency-adaptive detection threshold. In operation 1112, the digital filter is applied to the jitter trend, either using time-domain convolution or equivalently, by frequency-domain multiplication by the complex jitter spectrum followed by inverse transform. FIG. 13 illustrates an example of the resulting plot 1300 in the frequency domain.

In operation 1114, the kurtosis of the filtered jitter is computed by the processor 916 and/or the jitter analyzer 904 to determine whether the result from operation 1112 is likely to be predominantly Gaussian. If the kurtosis is greater than some kurtosis threshold, the filtered jitter is deemed to be entirely Gaussian since any bounded component would have insignificant effect on any subsequent error modeling. The kurtosis threshold may be preset in the memory 910, entered by a user through user inputs 114, or determined by the processor 916 and/or jitter analyzer 904. The kurtosis threshold may be set to be approximately 2.8, which, as described above, is intentionally somewhat below the value of 3.0 that kurtosis tends to near as the sample size grows for Gaussian distributed random jitter. The term “approximately” is used to indicate a possible variation of ±15% of a stated or understood value.

In operation 1116, if the kurtosis is less than or equal to the kurtosis threshold, the filtered jitter is deemed to have a bounded component worthy of further analysis by use of the Q-scale. The purpose of the Q-scale analysis is to divide the filtered jitter proportionately between the bounded and unbounded (Gaussian) categories. The samples of the jitter can be sorted by magnitude, and then converted to the Q-scale using an inverse error function, as will be understood by one skilled in the art. Unlike a situation in which the jitter distribution from the entire frequency band of jitter is graphed on the Q-scale, as discussed above, in this case, only a portion of the spectrum band-limited based on spectral magnitude and screened for likelihood of extra jitter is graphed.

In operation 1118, a linear asymptote is fitted to the portion of the Q-scale plot extending to the lower left. The reciprocal of the slope of this line can be recorded as σ_{L}, the Gaussian sigma corresponding to the left side of the distribution.

Similarly, in operation 1120, a linear asymptote is fitted to the portion of the Q-scale plot extending to the upper right. The reciprocal of the slope of this line can be recorded as σ_{R}, the Gaussian sigma corresponding to the right side of the distribution.

The standard deviation of the Gaussian jitter within the spectral hump σ_{H} is computed as (σ_{L}+σ_{R})/2, in operation 1122, and the intercept of the two asymptotes with the horizontal axis is recorded as the dual-Dirac magnitude of the bounded random jitter

A filter complementary to the filter generated in operation 1110 is generated in operation 1124. The complementary filter is a filter that removes areas of the spectrum that exceed the detection threshold. This filter is applied to the jitter trend, and the root mean square (rms) value of this filtered jitter is taken as an estimate of the Gaussian random jitter of the “white” portion of the spectrum, σ_{W}.

In operation 1126, the standard deviation of the overall Gaussian random jitter may then be determined as sqrt(σ_{W}²+σ_{H}²). This may allow the test and measurement instrument 900 to then more accurately display to the user the type of jitter present in the input signal, including deterministic components, random jitter, and Gaussian jitter.

Aspects of the disclosure may operate on particularly created hardware, firmware, digital signal processors, or on a specially programmed computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a computer readable storage medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or computer-readable storage media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the technologies disclosed herein are provided below. An embodiment of the technologies may include any one or more, and any combination of, the examples described below.

Example 1 a test and measurement device, comprising an input for receiving an input waveform; a converter coupled to the input and structured to generate a jitter trend, a corresponding complex jitter spectrum and a corresponding jitter spectral power signal from the received input waveform; a first threshold detector structured to identify first ranges of the jitter spectral power signal that are in excess of a first threshold to identify deterministic jitter; a first filter structured to exclude the ranges of the jitter spectral power signal that are in excess of the first threshold to generate a complex jitter spectrum for non-deterministic jitter and a corresponding jitter spectral power signal for non-deterministic jitter; a second threshold detector structured to identify second ranges of the spectral power signal for non-deterministic jitter that are in excess of the second threshold; a second filter structured to retain only the identified second ranges of the non-deterministic jitter; a Gaussian detector structured to determine whether the retained second ranges of the non-deterministic jitter contain primarily Gaussian or a mix of Gaussian and non-Gaussian jitter; and a Q-scale analyzer structured to perform further signal analysis only if the Gaussian detector determined that the jitter in the retained second ranges of the non-deterministic jitter contains non-Gaussian jitter.

Example 2 is the test and measurement device according to example 1, in which the further signal analysis performed by the Q-scale analyzer comprises determining one or more Q-scale parameters for the retained second ranges of non-deterministic jitter; and determining a standard deviation of the Gaussian jitter based on the one or more Q-scale parameters.

Example 3 is the test and measurement device according to example 2, wherein determining the standard deviation of the Gaussian jitter based on the one or more Q-scale parameters includes: determining a left-side standard deviation based on a Q-scale parameter; determining a right-side standard deviation based on a Q-scale parameter; determining a standard deviation for the Gaussian jitter in the retained second ranges of non-deterministic jitter; generating a filter complementary to the second filter and to exclude the second ranges of the non-deterministic jitter to determine an estimate of the Gaussian jitter not within the second ranges; determining the standard deviation of the Gaussian jitter not in the second ranges; and determining the standard deviation of the overall Gaussian jitter based on the standard deviations of the non-deterministic Gaussian jitter within and not within the second ranges.

Example 4 is the test and measurement device according to any one of examples 1-3, wherein the first threshold and the second threshold are frequency-adaptive thresholds, and the second threshold varies more slowly with frequency than the first threshold.

Example 5 is the test and measurement device according to any one of examples 1-4, wherein the Gaussian detector is structured to determine if the retained second ranges of the non-deterministic jitter contain primarily Gaussian or a mixture of Gaussian and non-Gaussian jitter by determining a kurtosis of the retained second ranges, and when the kurtosis is less than or equal to a kurtosis threshold, the Gaussian detector determines that the retained second ranges include non-Gaussian jitter.

Example 6 is the test and measurement device according to example 5, wherein the kurtosis threshold is approximately 2.8.

Example 7 is the test and measurement device according to examples 6, further comprising a user input structured to receive the kurtosis threshold.

Example 8 is the test and measurement device according to claim 1, wherein the second filter is a digital bandpass filter with one or more pass bands.

Example 9 is the method for determining jitter in an input signal, comprising: receiving an input signal; generating a spectral power signal from the received input signal; identifying first ranges of the spectral power signal that are in excess of a threshold; excluding by means of a first filter the identified first ranges of the jitter to extract the non-deterministic jitter; taking the magnitude of the non-deterministic jitter spectrum to identify the spectral power signal for the non-deterministic jitter; identifying second ranges of the of the spectral power signal for the non-deterministic jitter that are in excess of a second threshold; retaining only the identified second ranges of the non-deterministic jitter by a second filter; determining whether the retained second ranges of the spectral power signal of the non-deterministic jitter contain primarily Gaussian or Gaussian plus non-Gaussian jitter; and performing further signal analysis only if the Gaussian detector determined that the jitter in the retained second ranges of the non-deterministic jitter contains non-Gaussian jitter.

Example 10 is the method according to example 9, wherein the further signal analysis includes: determining one or more Q-scale parameters for the retained second ranges of non-deterministic jitter; and determining a standard deviation of the Gaussian jitter based on the one or more Q-scale parameters.

Example 11 is the method according to example 10, wherein determining the standard deviation of the Gaussian jitter based on the Q-scale parameter includes: determining a left-side standard deviation based on a Q-scale parameter; determining a right-side standard deviation based on a Q-scale parameter; determining a standard deviation for the Gaussian jitter in the retained second ranges of non-deterministic jitter; generating a filter complementary to the second filter to exclude the second ranges to determine an estimate of the Gaussian jitter not within the second ranges; determining the standard deviation of the Gaussian jitter not in the second ranges; and determining the standard deviation of the overall Gaussian jitter based on the standard deviations of the non-deterministic Gaussian jitter within and not within the second ranges.

Example 12 is the method according to any one of examples 9-11, wherein the second threshold is a frequency-adaptive threshold that adapts more slowly versus frequency than the first threshold.

Example 13 is the method according to example 9-12, wherein determining whether the retained second ranges of the non-deterministic jitter contains primarily Gaussian or Gaussian plus non-Gaussian jitter includes determining a kurtosis of the retained ranges, and when the kurtosis is less than or equal to a kurtosis threshold, the Gaussian detector determines that the retained second ranges includes non-Gaussian jitter.

Example 14 is the method according to example 13, wherein the kurtosis threshold is approximately 2.8.

Example 15 is the method according to any one of examples 9-14, wherein the second filter is a digital bandpass filter with one or more pass bands.

Example 16 is the one or more computer-readable storage media comprising instructions, which, when executed by one or more processors of a test and measurement instrument, cause the test and measurement instrument to: receive an input signal; generate a jitter spectrum and corresponding spectral power signal for non-deterministic jitter from the received input signal; identify ranges of the spectral power signal that are in excess of a threshold; retain by use of a filter the identified ranges of the non-deterministic jitter; determine whether the retained ranges of the non-deterministic jitter contains primarily Gaussian or Gaussian plus non-Gaussian jitter; and perform further signal analysis only if the Gaussian detector determined that the jitter in the filtered ranges of the spectral power signal contains non-Gaussian jitter.

Example 17 is the one or more computer-readable storage media according to example 16, further comprising instructions to cause the test and measurement instrument to perform further signal analysis by determining one or more Q-scale parameters for the portion of the non-deterministic jitter; and determining a standard deviation of the Gaussian jitter based on the one or more Q-scale parameters.

Example 18 is the one or more computer-readable storage media according to example 17, further comprising instructions to cause the test and measurement instrument to determine the standard deviation of the Gaussian jitter based on the Q-scale parameter by determining a left-side standard deviation based on a Q-scale parameter; determining a right-side standard deviation based on a Q-scale parameter; determining a standard deviation for the Gaussian jitter in the retained second ranges of non-deterministic jitter; generating a filter complementary to the filter and thereby excluding the ranges to determine an estimate of the Gaussian jitter not within the second ranges; determining the standard deviation of the Gaussian jitter not in the ranges; and determining the standard deviation of the Gaussian jitter based on the standard deviations of the non-deterministic Gaussian jitter within and not within the ranges.

Example 19 is the one or more computer-readable storage media according to any one of examples 16-18, wherein the first threshold is a frequency-adaptive thresholds that varies slowly with frequency.

Example 20 is the one or more computer-readable storage media according to any one of examples 16-19, further comprising instructions to determine whether the retained second ranges of the non-deterministic jitter contains primarily Gaussian or Gaussian plus non-Gaussian jitter by determining a kurtosis of the retained ranges, and when the kurtosis is less than or equal to a kurtosis threshold, the Gaussian detector determines that the retained second ranges includes non-Gaussian jitter.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

We claim:

1. A test and measurement device, comprising:
an input for receiving an input waveform;
a converter coupled to the input and structured to generate a jitter trend, a corresponding complex jitter spectrum and a corresponding jitter spectral power signal from the received input waveform;
a first threshold detector structured to identify first ranges of the jitter spectral power signal that are in excess of a first threshold to identify deterministic jitter;
a first filter structured to exclude the ranges of the jitter spectral power signal that are in excess of the first threshold to generate a complex jitter spectrum for non-deterministic jitter and a corresponding jitter spectral power signal for non-deterministic jitter;
a second threshold detector structured to identify second ranges of the spectral power signal for non-deterministic jitter that are in excess of the second threshold;
a second filter structured to retain only the identified second ranges of the non-deterministic jitter;
a Gaussian detector structured to determine whether the retained second ranges of the non-deterministic jitter contain primarily Gaussian or a mix of Gaussian and non-Gaussian jitter; and
a Q-scale analyzer structured to perform further signal analysis only if the Gaussian detector determined that the jitter in the retained second ranges of the non-deterministic jitter contains non-Gaussian jitter.

2. The test and measurement device according to claim 1, in which the further signal analysis performed by the Q-scale analyzer comprises:
determining one or more Q-scale parameters for the retained second ranges of non-deterministic jitter; and
determining a standard deviation of the Gaussian jitter based on the one or more Q-scale parameters.

3. The test and measurement device according to claim 2, wherein determining the standard deviation of the Gaussian jitter based on the one or more Q-scale parameters includes:
determining a left-side standard deviation based on a Q-scale parameter;
determining a right-side standard deviation based on a Q-scale parameter;
determining a standard deviation for the Gaussian jitter in the retained second ranges of non-deterministic jitter;
generating a filter complementary to the second filter and to exclude the second ranges of the non-deterministic jitter to determine an estimate of the Gaussian jitter not within the second ranges;
determining the standard deviation of the Gaussian jitter not in the second ranges; and
determining the standard deviation of the overall Gaussian jitter based on the standard deviations of the non-deterministic Gaussian jitter within and not within the second ranges.

4. The test and measurement device according to claim 1, wherein the first threshold and the second threshold are frequency-adaptive thresholds, and the second threshold varies more slowly with frequency than the first threshold.

5. The test and measurement device according to claim 1, wherein the Gaussian detector is structured to determine if the retained second ranges of the non-deterministic jitter contain primarily Gaussian or a mixture of Gaussian and non-Gaussian jitter by determining a kurtosis of the retained second ranges, and when the kurtosis is less than or equal to a kurtosis threshold, the Gaussian detector determines that the retained second ranges include non-Gaussian jitter.

6. The test and measurement device according to claim 5, wherein the kurtosis threshold is approximately 2.8.

7. The test and measurement device according to claim 6, further comprising a user input structured to receive the kurtosis threshold.

8. The test and measurement device according to claim 1, wherein the second filter is a digital bandpass filter with one or more pass bands.

9. A method for determining jitter in an input signal, comprising:
receiving an input signal;
generating a spectral power signal from the received input signal;
identifying first ranges of the spectral power signal that are in excess of a threshold;
excluding by means of a first filter the identified first ranges of the jitter to extract the non-deterministic jitter;
taking the magnitude of the non-deterministic jitter spectrum to identify the spectral power signal for the non-deterministic jitter;
identifying second ranges of the of the spectral power signal for the non-deterministic jitter that are in excess of a second threshold;
retaining only the identified second ranges of the non-deterministic jitter by a second filter;
determining whether the retained second ranges of the spectral power signal of the non-deterministic jitter contain primarily Gaussian or Gaussian plus non-Gaussian jitter; and
performing further signal analysis only if the Gaussian detector determined that the jitter in the retained second ranges of the non-deterministic jitter contains non-Gaussian jitter.

10. The method according to claim 9, wherein the further signal analysis includes:
determining one or more Q-scale parameters for the retained second ranges of non-deterministic jitter; and
determining a standard deviation of the Gaussian jitter based on the one or more Q-scale parameters.

11. The method according to claim 10, wherein determining the standard deviation of the Gaussian jitter based on the Q-scale parameter includes:
determining a left-side standard deviation based on a Q-scale parameter;
determining a right-side standard deviation based on a Q-scale parameter;
determining a standard deviation for the Gaussian jitter in the retained second ranges of non-deterministic jitter;
generating a filter complementary to the second filter to exclude the second ranges to determine an estimate of the Gaussian jitter not within the second ranges;
determining the standard deviation of the Gaussian jitter not in the second ranges; and
determining the standard deviation of the overall Gaussian jitter based on the standard deviations of the non-deterministic Gaussian jitter within and not within the second ranges.

12. The method according to claim 9, wherein the second threshold is a frequency-adaptive threshold that adapts more slowly versus frequency than the first threshold.

13. The method according to claim 9, wherein determining whether the retained second ranges of the non-deterministic jitter contains primarily Gaussian or Gaussian plus non-Gaussian jitter includes determining a kurtosis of the retained ranges, and when the kurtosis is less than or equal to a kurtosis threshold, the Gaussian detector determines that the retained second ranges includes non-Gaussian jitter.

14. The method according to claim 13, wherein the kurtosis threshold is approximately 2.8.

15. The method according to claim 9, wherein the second filter is a digital bandpass filter with one or more pass bands.

16. One or more computer-readable storage media comprising instructions, which, when executed by one or more processors of a test and measurement instrument, cause the test and measurement instrument to:
receive an input signal;
generate a jitter spectrum and corresponding spectral power signal for non-deterministic jitter from the received input signal;
identify ranges of the spectral power signal that are in excess of a threshold;
retain by use of a filter the identified ranges of the non-deterministic jitter;
determine whether the retained ranges of the non-deterministic jitter contains primarily Gaussian or Gaussian plus non-Gaussian jitter; and
perform further signal analysis only if the Gaussian detector determined that the jitter in the filtered ranges of the spectral power signal contains non-Gaussian jitter.

17. The one or more computer-readable storage media according to claim 16, further comprising instructions to cause the test and measurement instrument to perform further signal analysis by:
determining one or more Q-scale parameters for the portion of the non-deterministic jitter; and
determining a standard deviation of the Gaussian jitter based on the one or more Q-scale parameters.

18. The one or more computer-readable storage media according to claim 17, further comprising instructions to cause the test and measurement instrument to determine the standard deviation of the Gaussian jitter based on the Q-scale parameter by:
determining a left-side standard deviation based on a Q-scale parameter;
determining a right-side standard deviation based on a Q-scale parameter;
determining a standard deviation for the Gaussian jitter in the retained second ranges of non-deterministic jitter;
generating a filter complementary to the filter and thereby excluding the ranges to determine an estimate of the Gaussian jitter not within the second ranges;
determining the standard deviation of the Gaussian jitter not in the ranges; and
determining the standard deviation of the Gaussian jitter based on the standard deviations of the non-deterministic Gaussian jitter within and not within the ranges.

19. The one or more computer-readable storage media according to claim 16, wherein the first threshold is a frequency-adaptive thresholds that varies slowly with frequency.

20. The one or more computer-readable storage media according to claim 16, further comprising instructions to determine whether the retained second ranges of the non-deterministic jitter contains primarily Gaussian or Gaussian plus non-Gaussian jitter by determining a kurtosis of the retained ranges, and when the kurtosis is less than or equal to a kurtosis threshold, the Gaussian detector determines that the retained second ranges includes non-Gaussian jitter.
